(19) United States
(12) Patent Application Publication
(10) Pub. No.: US 2017/0040353 A1
(43) Pub. Date: Feb. 9, 2017

(54) MANUFACTURING METHOD FOR ARRAY SUBSTRATE, ARRAY SUBSTRATE AND DISPLAY PANEL

(71) Applicant: Shenzhen China Star Optoelectronics Technology Co., Ltd., Shenzhen, Guangdong (CN)

(72) Inventors: Xiaowen LV, Shenzhen, Guangdong (CN); Chih-yuan TSENG, Shenzhen, Guangdong (CN)

(73) Assignee: Shenzhen China Star Optoelectronics Technology Co., Ltd., Shenzhen, Guangdong (CN)

(21) Appl. No.: 14/443,968

(22) PCT Filed: Apr. 16, 2015
(86) PCT No.: PCT/CN2015/076726

§ 371 Date: May 19, 2015

(30) Foreign Application Priority Data
Apr. 1, 2015 (CN) 201510152388.1

(51) Int. Cl. H01L 27/12; H01L 29/417; H01L 21/28; H01L 29/786

(52) U.S. Cl. CPC H01L 27/1288; H01L 27/1248; H01L 29/78606; H01L 29/41733; H01L 21/28

(57) ABSTRACT

The present discloses a manufacturing method for an array substrate, an array substrate and a display panel. The manufacturing method includes sequentially forming a first metal layer, an insulation layer, a first thin-film layer, a second metal layer and an inorganic layer on a substrate; forming a color resist layer on the inorganic layer; forming an organic layer on the inorganic layer and the color resist layer; digging a hole on the organic and the inorganic layer to form a first through hole so as to uncover a portion of the second metal layer; forming a second thin-film layer on the organic layer and the uncovered second metal layer. The present invention can reduce the damage of the metal layer and the number of the masks in the manufacturing process, and increase the yield

### BACKGROUND OF THE INVENTION

1. Field of the Invention

The present invention relates to a display field, and more particular to a manufacturing method for an array substrate, an array substrate and a display panel.

2. Description of Related Art

An Organic Light-Emitting Diode (OLED) has many advantages of self-luminous, wide viewing angle, fast response, thin, easy for flexible display field, and has become a hot research currently. Therefore, the OLED has become the mainstream of the next generation display technology following the Liquid Crystal Display (LCD) and the Plasma Display Panel (PDP).

An oxide semiconductor has a higher mobility, while an amorphous structure has a higher compatibility with the current a-Si manufacturing process so that the oxide semiconductor has been widely applied in manufacturing of a large-size OLED panel.

Structures of an oxide semiconductor thin-film-transistor (TFT) includes an etching stop layer (ESL) structure, a back channel etch (BCE) structure and a co-planar (CP) structure. The above structures have advantages and disadvantages. Wherein, the etching stop layer structure is better in stability because an etching stop layer can protect the oxide semiconductor. However, the etching stop layer structure requires an additional mask such that the coupling capacitance is larger, and is not conducive to improve yield rate and cost reduction.

### SUMMARY OF THE INVENTION

The technology solved by the present invention is to provide a manufacturing method for an array substrate, an array substrate and a display panel. The present invention can reduce the damage of the metal layer and reduced the number of the masks used in the manufacturing process in order to increase the yield rate.

In order to solve the above technology problems, a technology solution of the present invention is: a manufacturing method for an array substrate, comprising: sequentially forming a first metal layer, an insulation layer, a first thin-film layer, an etching stop layer, a second metal layer and an inorganic layer on a substrate; forming a color resist layer on the inorganic layer; forming an organic layer on the inorganic layer and the color resist layer; digging a hole on the organic layer and the inorganic layer in order to form a first through hole to make a portion of the second metal layer to be uncovered; and forming a second thin-film layer on the organic layer and the portion of the second metal layer which is uncovered.

Wherein, the step of sequentially forming a first metal layer, an insulation layer, a first thin-film layer, an etching stop layer, a second metal layer and an inorganic layer on a substrate specifically includes: forming the first metal layer and patterning the first metal layer in order to form a first metal electrode and a second metal electrode; forming the insulation layer on the first metal layer and substrate, and patterning the insulation layer in order to uncover a portion of the second metal electrode; forming the first thin-film layer on the insulation layer, and patterning the thin-film layer in order to form a first thin-film electrode and a second thin-film electrode to respectively correspond to the first metal electrode and the second metal electrode; forming the etching stop layer on the thin-film layer, and forming the second metal layer on the etching stop layer and the portion of the second metal electrode which is uncovered in order to respectively form a source electrode and a drain electrode; and forming the inorganic layer on the second metal layer.

Wherein, the step of forming the etching stop layer on the thin-film layer, and forming the second metal layer on the etching stop layer and the portion of the second metal electrode which is uncovered in order to respectively form a source electrode and a drain electrode specifically includes: respectively forming a first etching stop layer and a second etching stop layer on the first thin-film electrode and the second thin-film electrode; and forming the second metal layer on the first etching stop layer, the second etching stop layer and the portion of the second metal electrode which is uncovered, and patterning the second metal layer in order to form a source electrode and a drain electrode respectively on the first thin-film electrode and the second thin-film electrode so as to form a first island-shaped semiconductor and a second island-shaped semiconductor; wherein, a source electrode or a drain electrode of the first island-shaped semiconductor is connected with the portion of the second metal electrode which is uncovered.

Wherein, the step of forming a second thin-film layer on the organic layer and the portion of the second metal layer which is uncovered specifically includes: forming the second thin-film layer on the organic layer and the portion of the second metal layer which is uncovered, and patterning the second thin-film layer in order to form a third thin-film electrode; wherein, the third thin-film electrode is connected with the source electrode or the drain electrode of the second island-shaped semiconductor through the first through hole.

Wherein, in the step of digging a hole on the organic layer and the inorganic layer in order to form a first through hole to make a portion of the second metal layer to be uncovered specifically includes: ashing the organic layer, and using the organic layer as a photoresist layer for patterning the inorganic layer and digging the hole in order to form the first through hole.

Wherein, the step of forming a color resist layer on the inorganic layer specifically includes: respectively forming a red color resist, a green color resist, or a blue color resist.

Wherein, the first thin-film layer is made of IGZO and the second thin-film layer is made of ITO.

In order to solve the above technology problems, another technology solution of the present invention is: an array substrate, comprising: a substrate; and a first metal layer, an insulation layer, a first thin-film layer, an etching stop layer, a second metal layer, an inorganic layer, a color resist layer, an organic layer and a second thin-film layer disposed on the substrate; wherein, the second metal layer includes a source electrode and a drain electrode; the inorganic and the organic layer are provided with a first hole to make a portion of the source electrode or the drain electrode which is uncovered to be connected with the second thin-film layer.

In order to solve the above technology problems, another technology solution of the present invention is: a display panel, comprising: an array substrate including: a substrate; and a first metal layer, an insulation layer, a first thin-film layer, an etching stop layer, a second metal layer, an inorganic layer, a color resist layer, an organic layer and a second thin-film layer disposed on the substrate; wherein, the second metal layer includes a source electrode and a drain electrode; the inorganic and the organic layer are provided with a first hole to make a portion of the source electrode or the drain electrode which is uncovered to be connected with the second thin-film layer.

Comparing to the conventional art, in the manufacturing process of the array substrate of the present embodiment, after forming the inorganic layer, a through hole does not immediately form on the inorganic layer. Instead, a color resist layer (such as a red color resist, a green color resist, or a blue color resist) is formed on the inorganic layer first. After forming the organic layer on the color resist, forming a through hole on the organic layer and the inorganic layer to uncover the metal source electrode or the metal drain electrode. Accordingly, corrosion and damage of the metal source electrode or the metal drain electrode when forming a through hole first and then, forming a color resist in the conventional art is avoided. Besides, forming the through hole at the organic layer and the inorganic layer simultaneously can avoid the requirement for hole alignment problem when respectively forming through holes at the organic layer and the inorganic layer so that the aperture ratio of the display panel is increased and manufacturing process is decreased.

### BRIEF DESCRIPTION OF THE DRAWINGS

FIG. 1 is a flow chart of a manufacturing method for an array substrate according to a first embodiment of the present invention;

FIG. 2 is a schematic diagram of a step 101 of a manufacturing method for an array substrate according to a first embodiment of the present invention;

FIG. 3 is a schematic diagram of a step 102 of a manufacturing method for an array substrate according to a first embodiment of the present invention;

FIG. 4 is a schematic diagram of a step 103 of a manufacturing method for an array substrate according to a first embodiment of the present invention;

FIG. 5 is a schematic diagram of a step 104 of a manufacturing method for an array substrate according to a first embodiment of the present invention;

FIG. 6 is a schematic diagram of a step 105 of a manufacturing method for an array substrate according to a first embodiment of the present invention;

FIG. 7 is a flow chart of a manufacturing method for an array substrate according to a second embodiment of the present invention;

FIG. 8 is a schematic diagram of a step 701-705 of a manufacturing method for an array substrate according to a second embodiment of the present invention;

FIG. 9 is a schematic diagram of a step 706-709 of a manufacturing method for an array substrate according to a second embodiment of the present invention; and

FIG. 10 is a schematic diagram of an array substrate according to an embodiment of the present invention.

### DETAILED DESCRIPTION OF THE PREFERRED EMBODIMENT

The following content combines figures and embodiments for detail description of the present invention.

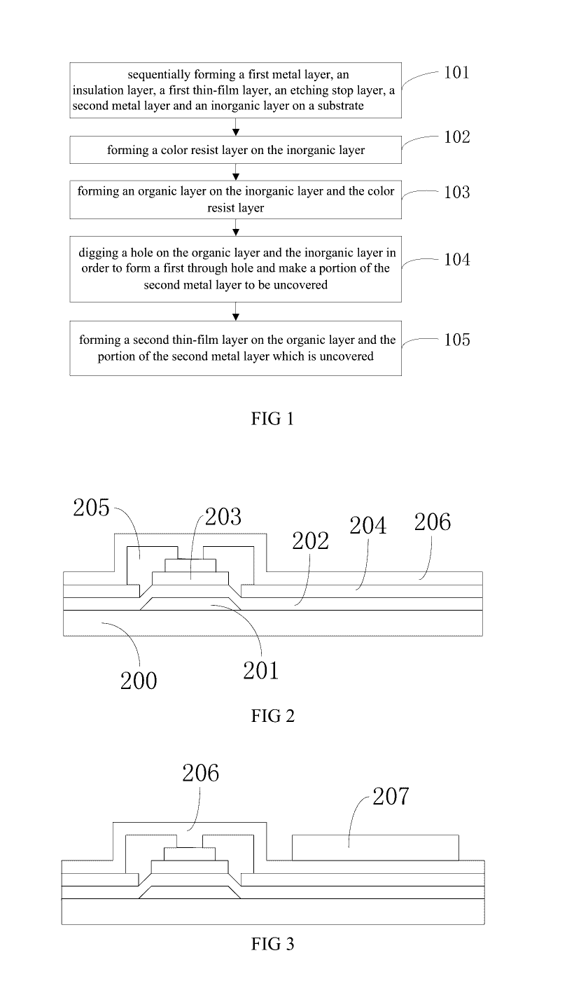

With reference to FIG. 1, FIG. 1 is a flow chart of a manufacturing method for an array substrate according to a first embodiment of the present invention. The method includes:

Step 101: sequentially forming a first metal layer 201, an insulation layer 202, a first thin-film layer 203, an etching stop layer 204, a second metal layer 205 and an inorganic layer 206 on a substrate 200;

As shown in FIG. 2, the step 101 specifically includes: depositing the first metal layer 201 on the substrate 200; wherein, the substrate 200 is generally a glass substrate;

forming the insulation layer 202 on the first metal layer 201, and the insulation layer 202 is also known as a gate insulation layer;

forming the first thin-film layer 203 on the insulation layer 202; patterning the thin-film layer 203 to make a size of the thin-film layer 203 to be corresponding to the first metal layer 201; wherein, the first thin-film layer 203 is generally a transparent semiconductor material such as IGZO. However, the first thin-film layer 203 can also be made by another similar material such as ITO;

forming an etching stop layer 204 on the first thin-film layer 203 and patterning the etching stop layer 204 to make two end portions of the first thin-film layer 203 to be uncovered;

depositing the second metal layer 205 at the uncovered end portions of the first thin-film layer 203; patterning the second metal layer 205 to respectively form a source electrode and a drain electrode, wherein, the source electrode and the drain electrode respectively correspond to two ends of the first thin-film layer 203;

forming an inorganic layer 206 on the etching stop layer 204 and the second metal layer 205.

Step 102: forming a color resist layer 207 on the inorganic layer 206;

As shown in FIG. 3, the step 102 specifically includes: respectively forming a red color resist, a green color resist or a blue color resist on the inorganic layer 206.

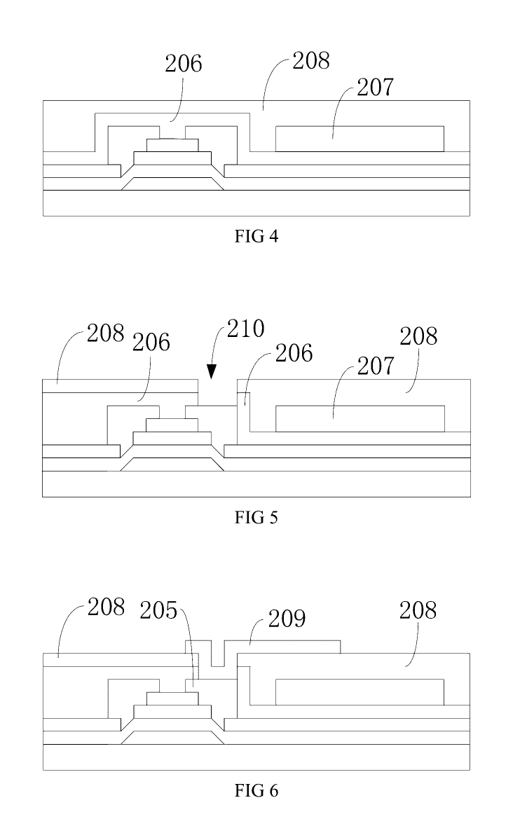

Step 103: forming an organic layer 208 on the inorganic layer 206 and the color resist layer 207; (as shown in FIG. 4)

Step 104: digging a hole on the organic layer 208 and the inorganic layer 206 in order to form a first through hole 210 and make a portion of the second metal layer 205 to be uncovered; (as shown in FIG. 5)

Step 105: forming a second thin-film layer 209 on the organic layer 208 and the portion of the second metal layer 205 which is uncovered. (as shown in FIG. 6)

Comparing to the conventional art, in the manufacturing process of the array substrate of the present embodiment, after forming the inorganic layer, a through hole does not immediately form on the inorganic layer. Instead, a color resist layer (such as a red color resist, a green color resist, or a blue color resist) is formed on the inorganic layer first. After forming the organic layer on the color resist, forming a through hole on the organic layer and the inorganic layer to uncover the metal source electrode or the metal drain electrode. Accordingly, corrosion and damage of the metal source electrode or the metal drain electrode when forming a through hole first and then, forming a color resist in the conventional art is avoided. Besides, forming the through hole at the organic layer and the inorganic layer simultaneously can avoid the requirement for hole alignment problem when respectively forming through holes at the organic layer and the inorganic layer so that the aperture ratio of the display panel is increased and manufacturing process is decreased.

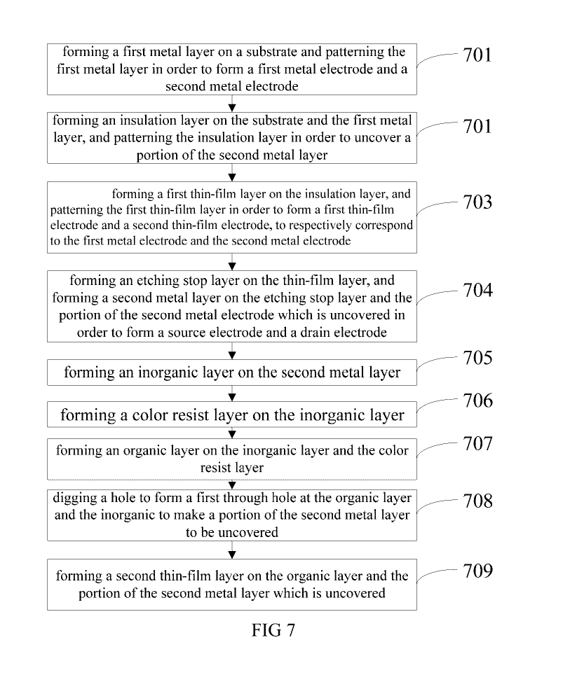

With reference to FIG. 7, FIG. 7 is a flow chart of a manufacturing method for an array substrate according to a second embodiment of the present invention. The method includes:

As shown in FIG. 8, FIG. 8 is a schematic diagram of a step 701-705 of a manufacturing method for an array substrate.

Step 701: forming a first metal layer on a substrate 800 and patterning the first metal layer in order to form a first metal electrode 8011 and a second metal electrode 8012;

Step 702: forming an insulation layer 802 on the substrate 800 and the first metal layer, and patterning the insulation layer 802 in order to uncover a portion of the second metal layer 8012.

Step 703: forming a first thin-film layer on the insulation layer 802, and patterning the first thin-film layer in order to form a first thin-film electrode 8031 and a second thin-film electrode 8032, to respectively correspond to the first metal electrode 8011 and the second metal electrode 8012;

Step 704: forming an etching stop layer 804 on the thin-film layer, and forming a second metal layer 805 on the etching stop layer 804 and the portion of the second metal electrode 8012 which is uncovered in order to form a source electrode and a drain electrode;

Step 705: forming an inorganic layer 806 on the second metal layer 805;

The above steps are similar as the first embodiment, and the difference is that two gate electrodes and two island-shaped semiconductors corresponding to the gate electrodes are formed on the substrate 800. After patterning the second metal layer 805, each semiconductor island has a source electrode and a drain electrode, wherein, the drain electrode or the source electrode of the first island-shaped semiconductor is connected with the gate electrode (that is, the second metal electrode 8012) of the second island-shaped semiconductor.

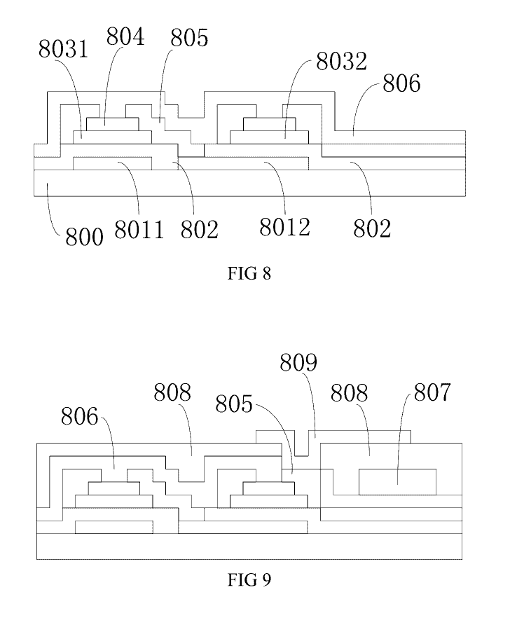

As shown in FIG. 9, and FIG. 9 is a schematic diagram of a step 706-709 of a manufacturing method for an array substrate according to a second embodiment of the present invention.

Step 706: forming a color resist layer 807 on the inorganic layer 806;

Step 707: forming an organic layer 808 on the inorganic layer 806 and the color resist layer 807;

Step 708: digging a hole to form a first through hole at the organic layer 808 and the inorganic layer 806 to make a portion of the second metal layer 805 to be uncovered;

Wherein, the portion of the second metal layer 805 which is uncovered is corresponding to the source electrode or the drain electrode of the second island-shaped semiconductor as shown in FIG. 9. Besides, the step of digging a hole to form a first through hole at the organic layer 808 and the inorganic layer 806 can be achieved through the following method:

Ashing the organic layer 808, and using the organic layer 808 as a photoresist layer to patterning the inorganic layer 806 in order to form the first through hole.

Step 709: forming a second thin-film layer 809 on the organic layer 807 and the portion of the second metal layer 805 which is uncovered.

The second thin-film layer 809 is generally made of indium tin oxide (ITO), and also can be made by other semiconductor materials which have similar functions such as IGZO and so on.

The step 709 is specifically:

forming the second thin-film layer 809 on the organic layer 808 and the portion of the second metal layer 805 which is uncovered, and patterning the second thin-film layer 809 in order to form a third thin-film electrode; wherein, a source electrode or a drain electrode of the second island-shaped semiconductor is connected with the third thin-film electrode through the first through hole.

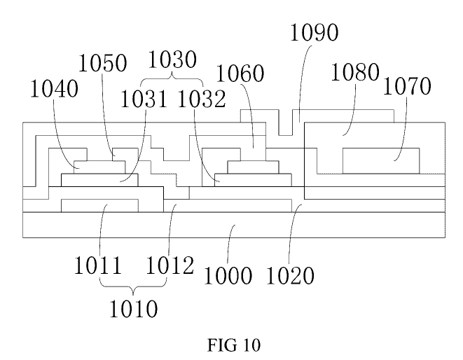

With reference to FIG. 10, and FIG. 10 is a schematic diagram of an array substrate according to an embodiment of the present invention. The array substrate includes: a substrate 1000, and a first metal layer 1010, an insulation layer 1020, a first thin-film layer 1030, an etching stop layer 1040, a second metal layer 1050, an inorganic layer 1060, a color resist layer 1070, an organic layer 1080 and a second thin-film layer 1090 sequentially formed on the substrate 1000. Wherein, the second metal layer 1050 includes a source electrode and a drain electrode; a first through hole is disposed at the inorganic layer 1060 and the organic layer 1080 to make the source electrode or the drain electrode which is uncovered to be connected with the second thin-film layer 1090.

Wherein, the first metal layer 1010 includes a first metal electrode 1011 and a second metal electrode 1012. The first thin-film layer 1030 includes a first thin-film electrode 1031 and a second thin-film electrode 1032 which are respectively correspondingly to the first metal electrode 1011 and the second metal electrode 1012. The second metal layer 1050 includes a first source electrode and a first drain electrode corresponding to the first thin-film electrode 1031, and the second metal layer 1050 also includes a second source electrode and a second drain electrode corresponding to the second thin-film electrode 1032. The first source electrode or the first drain electrode is connected with the second metal electrode 1012. The second source electrode or the second drain electrode is connected with the second thin-film layer 1090 through the first through hole.

Comparing to the conventional art, in the manufacturing process of the array substrate of the present embodiment, after forming the inorganic layer, a through hole does not immediately form on the inorganic layer. Instead, a color resist layer (such as a red color resist, a green color resist, or a blue color resist) is formed on the inorganic layer first. After forming the organic layer on the color resist, forming a through hole on the organic layer and the inorganic layer to uncover the metal source electrode or the metal drain electrode. Accordingly, corrosion and damage of the metal source electrode or the metal drain electrode when forming a through hole first and then, forming a color resist in the conventional art is avoided. Besides, forming the through hole at the organic layer and the inorganic layer simultaneously can avoid the requirement for hole alignment problem when respectively forming through holes at the organic layer and the inorganic layer so that the aperture ratio of the display panel is increased and manufacturing process is decreased.

In addition, the present invention also provides a display panel; the display panel includes the array substrates described at above embodiments.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. A manufacturing method for an array substrate, comprising:
sequentially forming a first metal layer, an insulation layer, a first thin-film layer, an etching stop layer, a second metal layer and an inorganic layer on a substrate;
forming a color resist layer on the inorganic layer;
forming an organic layer on the inorganic layer and the color resist layer;
digging a hole on the organic layer and the inorganic layer in order to form a first through hole to make a portion of the second metal layer to be uncovered; and
forming a second thin-film layer on the organic layer and the portion of the second metal layer which is uncovered.

2. The manufacturing method according to claim 1, wherein, the step of sequentially forming a first metal layer, an insulation layer, a first thin-film layer, an etching stop layer, a second metal layer and an inorganic layer on a substrate specifically includes:
forming the first metal layer and patterning the first metal layer in order to form a first metal electrode and a second metal electrode;
forming the insulation layer on the first metal layer and substrate, and patterning the insulation layer in order to uncover a portion of the second metal electrode;
forming the first thin-film layer on the insulation layer, and patterning the thin-film layer in order to form a first thin-film electrode and a second thin-film electrode to respectively correspond to the first metal electrode and the second metal electrode;
forming the etching stop layer on the thin-film layer, and forming the second metal layer on the etching stop layer and the portion of the second metal electrode which is uncovered in order to respectively form a source electrode and a drain electrode; and
forming the inorganic layer on the second metal layer.

3. The manufacturing method according to claim 2, the step of forming the etching stop layer on the thin-film layer, and forming the second metal layer on the etching stop layer and the portion of the second metal electrode which is uncovered in order to respectively form a source electrode and a drain electrode specifically includes:
respectively forming a first etching stop layer and a second etching stop layer on the first thin-film electrode and the second thin-film electrode; and
forming the second metal layer on the first etching stop layer, the second etching stop layer and the portion of the second metal electrode which is uncovered, and patterning the second metal layer in order to form a source electrode and a drain electrode respectively on the first thin-film electrode and the second thin-film electrode so as to form a first island-shaped semiconductor and a second island-shaped semiconductor;
wherein, a source electrode or a drain electrode of the first island-shaped semiconductor is connected with the portion of the second metal electrode which is uncovered.

4. The manufacturing method according to claim 3, wherein, the step of forming a second thin-film layer on the organic layer and the portion of the second metal layer which is uncovered specifically includes:
forming the second thin-film layer on the organic layer and the portion of the second metal layer which is uncovered, and patterning the second thin-film layer in order to form a third thin-film electrode;
wherein, the third thin-film electrode is connected with the source electrode or the drain electrode of the second island-shaped semiconductor through the first through hole.

5. The manufacturing method according to claim 1, in the step of digging a hole on the organic layer and the inorganic layer in order to form a first through hole to make a portion of the second metal layer to be uncovered specifically includes:
ashing the organic layer, and using the organic layer as a photoresist layer for patterning the inorganic layer and digging the hole in order to form the first through hole.

6. The manufacturing method according to claim 1, wherein, the step of forming a color resist layer on the inorganic layer specifically includes:
respectively forming a red color resist, a green color resist, or a blue color resist.

7. The manufacturing method according to claim 1, wherein, the first thin-film layer is made of IGZO and the second thin-film layer is made of ITO.

8. An array substrate, comprising:
a substrate; and
a first metal layer, an insulation layer, a first thin-film layer, an etching stop layer, a second metal layer, an inorganic layer, a color resist layer, an organic layer and a second thin-film layer disposed on the substrate;
wherein, the second metal layer includes a source electrode and a drain electrode; the inorganic and the organic layer are provided with a first hole to make a portion of the source electrode or the drain electrode which is uncovered to be connected with the second thin-film layer.

9. The array substrate according to claim 8, wherein, the first metal layer includes a first metal electrode and a second metal electrode, and the first thin-film layer includes a first thin-film electrode and a second thin-film electrode which are respectively corresponding to the first metal electrode and the second metal electrode;
the second metal layer includes a first source electrode and a first drain electrode which are corresponding to the first thin-film electrode;
the second metal layer also includes a second source electrode and a second drain electrode which are corresponding to the second thin-film electrode;
the first source electrode or the first drain electrode is connected with the second metal electrode;
the second source electrode or the second drain electrode is connected with the second thin-film layer through the first through hole.

10. The array substrate according to claim 8, wherein, the color resist layer includes a red color resist, a green color resist, or a blue color resist.

11. The array substrate according to claim 8, wherein, the first thin-film layer is made of IGZO and the second thin-film layer is made of ITO.

12. A display panel, comprising:
an array substrate including:
a substrate; and
a first metal layer, an insulation layer, a first thin-film layer, an etching stop layer, a second metal layer, an inorganic layer, a color resist layer, an organic layer and a second thin-film layer disposed on the substrate;
wherein, the second metal layer includes a source electrode and a drain electrode; the inorganic and the organic layer are provided with a first hole to make a portion of the source electrode or the drain electrode which is uncovered to be connected with the second thin-film layer.

13. The display panel according to claim 12, wherein, the first metal layer includes a first metal electrode and a second metal electrode, and the first thin-film layer includes a first thin-film electrode and a second thin-film electrode which are respectively corresponding to the first metal electrode and the second metal electrode;
the second metal layer includes a first source electrode and a first drain electrode which are corresponding to the first thin-film electrode;
the second metal layer also includes a second source electrode and a second drain electrode which are corresponding to the second thin-film electrode;
the first source electrode or the first drain electrode is connected with the second metal electrode;
the second source electrode or the second drain electrode is connected with the second thin-film layer through the first through hole.

14. The display panel according to claim 12, wherein, the color resist layer includes a red color resist, a green color resist or a blue color resist.

15. The display panel according to claim 12, wherein, the first thin-film layer is made of IGZO and the second thin-film layer is made of ITO.
